(19) United States
(12) Patent Application Publication
(10) Pub. No.: US 2010/0213789 A1
(43) Pub. Date: Aug. 26, 2010

(54) ELECTROSTATIC DRIVE MEMS ELEMENT AND METHOD OF PRODUCING THE SAME

(76) Inventor: Yasushi IGARASHI, Tokyo (JP)

Correspondence Address: Kubotera & Associates, LLC, 200 Daingerfield Rd, Suite 202, Alexandria, VA, 22314, US

(21) Appl. No.: 12/707,928

(22) Filed: Feb. 18, 2010

(30) Foreign Application Priority Data
Feb. 26, 2009 (JP) 2009-044562

(51) Int. Cl. H02N 11/00; H01L 21/443

(52) U.S. Cl. 310/300; 438/585; 257/E21.478

(57) ABSTRACT

An electrostatic drive MEMS (Micro Electro Mechanical Systems) element includes a substrate; a fixed electrode disposed on the substrate; a movable electrode arranged to face the fixed electrode in a vertical direction and be movable toward the fixed electrode through an electrostatic force generated between the fixed electrode and the movable electrode; and an insulation film disposed on one of an upper surface of the fixed electrode and a lower surface of the movable electrode and formed of an insulation member containing a conductive fine particle.

### BACKGROUND OF THE INVENTION AND RELATED ART STATEMENT

The present invention relates to an electrostatic drive MEMS (Micro Electro Mechanical Systems) element and a method of the electrostatic drive MEMS element.

Recently, as an electrical device has a smaller size, an electrostatic drive MEMS (Micro Electro Mechanical Systems) element has been used in various devices such as a DMD (Digital Micro-mirror Device) as an optical element, a head of an ink jet printer, a pressure sensor, a gyroscope, an acceleration sensor, a flow sensor, and the like.

Among conventional MEMS elements with various actuation methods, a conventional electrostatic drive MEMS element is actuated with an electrostatic force. The conventional electrostatic drive MEMS element has a structure formed of a substrate, a fixed electrode disposed on the substrate, a movable electrode arranged to face the fixed electrode, and an insulation film disposed on an upper surface of the fixed electrode or a lower surface of the movable electrode (referred to as between drive electrodes).

In the conventional electrostatic drive MEMS element described above, electric charges may be accumulated in the insulation film. When electric charges are accumulated in the insulation film, the insulation film may stick to the movable electrode or the fixed electrode due to electric charges, thereby causing a phenomenon called a stiction phenomenon.

Non-Patent Reference 1 has disclosed a counter measure to the stiction phenomenon, i.e., an issue of the conventional electrostatic drive MEMS element. According to a method (Intelligent Bipolar Actuation) disclosed in Non-Patent Reference 1, an electric charge amount in an insulation film between drive electrodes is monitored. When the electric charge amount becomes a specific level, polarities of the drive electrodes are reversed. Accordingly, electric charges in the insulation film are released, thereby preventing the stiction phenomenon.

Non-Patent Reference 1: Toshiba Review “RF MEMS Variable Capacitance Element”, Vol. 63, No. 2 (2008)

Non-Patent Reference 2 has disclosed another counter measure to the stiction phenomenon. According to Non-Patent Reference 2, several layers formed of Al₂O₃ and ZnO are deposited through atomic layer deposition (ALD) to adjust an electrical resistivity of an insulation film, so that electric charges are not accumulated in the insulation film, thereby preventing the stiction phenomenon.

Non-Patent Reference 2: International Microwave Symposium Digest, “Atomic Layer Deposition of Al₂O₃/ZnO Nano-scale Films for Gold RF MEMS”, (2004)

Patent Reference 1 has disclosed a method, in which a barrier metal layer formed of a metal nitride film such as a TSiN film and a WSiN film is provided between wiring layers or an insulation film and an electrode. Accordingly, it is possible to improve contact property between the wiring layers or the insulation film and the electrode.

Patent Reference 1: Japanese Patent Publication No. 08-139092

Patent Reference 2 has disclosed another method, in which a semiconductor layer is disposed between drive electrodes. Accordingly, it is possible to reduce an electric charge amount in the semiconductor layer using a Schottky barrier, thereby preventing the stiction phenomenon.

Patent Reference 2: Japanese Patent Publication No. 2006-32339

According to Non-Patent Reference 1, the control circuit called IBA is adopted to prevent the stiction phenomenon. Accordingly, it is necessary to perform a step of comparing a capacitance for control, thereby increasing an operation time. Further, an entire power consumption of the control circuit tends to increase due to IBA.

According to Non-Patent Reference 2, it is necessary to deposit fifty layers of each of Al₂O₃ and ZnO. Accordingly, it is necessary to perform ALD for a long period of time. Further, it is necessary to use a special ALD device, i.e., an expensive device.

According to Patent Reference 1, when the metal barrier layer is formed, a flow ratio of nitrogen gas is adjusted to control the electric resistivity. As a result, the metal barrier layer has the electric resistivity less than 1×10⁻³ Ωcm, so that the metal barrier layer is used as a conductive member. According to Patent Reference 1, it is difficult to adjust the flow ratio of nitrogen gas to obtain the electric resistivity of the metal barrier layer at a level of an insulation member with more than 1×10⁵ Ωcm, especially more than 1×10⁸ Ωcm. Accordingly, it is difficult to prevent the stiction phenomenon with the metal barrier layer disclosed in Patent Reference 1.

According to Patent Reference 2, it is difficult to form the Schottky barrier with a uniform property, and further difficult to control a property of the Schottky barrier. Accordingly, it is difficult to form a uniform Schottky barrier at an interface where a movable electrode contacts with the semiconductor layer. As a result, it is difficult to completely prevent the stiction phenomenon.

In view of the problems described above, an object of the present invention is to provide an electrostatic drive MEMS element and a method of producing the electrostatic drive MEMS element capable of solving the problems of the conventional electrostatic drive MEMS element. In the present invention, the electrostatic drive MEMS element is capable of preventing the stiction phenomenon through adjusting an electric resistivity of an insulation film without an additional circuit.

Further objects and advantages of the invention will be apparent from the following description of the invention.

### SUMMARY OF THE INVENTION

In order to attain the objects described above, according to a first aspect of the present invention, an electrostatic drive MEMS (Micro Electro Mechanical Systems) element includes a substrate; a fixed electrode disposed on the substrate; a movable electrode arranged to face the fixed electrode in a vertical direction and be movable toward the fixed electrode through an electrostatic force generated between the fixed electrode and the movable electrode; and an insulation film disposed on one of an upper surface of the fixed electrode and a lower surface of the movable electrode and formed of an insulation member containing a conductive fine particle.

According to a second aspect of the present invention, in the electrostatic drive MEMS element in the first aspect, the insulation member is formed of a nitride containing at least one element in a semiconductor element group or a metal element group except a transition metal element group. The conductive fine particle is formed of a nitride containing at least one element in the transition metal element group.

According to a third aspect of the present invention, in the electrostatic drive MEMS element in the second aspect, the insulation member is formed of SiN or AlN. The conductive fine particle is formed of WN, TaN, MoN, TiN, ZrN or HfN.

According to a fourth aspect of the present invention, in the electrostatic drive MEMS element in the first to third aspects, the insulation member is formed of an amorphous material. The conductive fine particle is formed of an amorphous material or a fine crystalline material.

According to a fifth aspect of the present invention, in the electrostatic drive MEMS element in the first to fourth aspects, the insulation film has an undulation surface at least on a side of the movable electrode.

According to a sixth aspect of the present invention, in the electrostatic drive MEMS element in the first to fifth aspects, the insulation film is disposed on the upper surface of the fixed electrode.

According to a seventh aspect of the present invention, a method of producing an electrostatic drive MEMS element includes the steps of: forming a fixed electrode on a substrate using a conductive material; forming an insulation film on an upper surface of the fixed electrode using a gas mixture having a flow ratio of nitrogen gas greater than 80% so that at least one element in a transition metal element group and one element in a semiconductor element group or a metal element group except the transition metal element group are used as raw materials; forming a sacrifice film on the insulation film; forming a movable electrode on the sacrifice film using a conductive material; and removing the sacrifice film.

According to an eighth aspect of the present invention, a method of producing an electrostatic drive MEMS element includes the steps of: forming a fixed electrode on a substrate using a conductive material; forming a sacrifice film on the fixed electrode; forming an insulation film on an upper surface of the sacrifice film using a gas mixture having a flow ratio of nitrogen gas greater than 80% so that at least one element in a transition metal element group and one element in a semiconductor element group or a metal element group except the transition metal element group are used as raw materials; forming a movable electrode on the insulation film using a conductive material; and removing the sacrifice film.

According to a ninth aspect of the present invention, in the method of producing the electrostatic drive MEMS element in the seventh and eighth aspects, in the step of forming the insulation film, the insulation film is formed so that the one element in the semiconductor element group or the metal element group has a compositional ratio greater than two relative to the one element in the transition metal element group.

According to a tenth aspect of the present invention, in the method of producing the electrostatic drive MEMS element in the seventh and ninth aspects, in the step of forming the insulation film, the insulation film is formed so that the one element in the semiconductor element group or the metal element group is Si or Al, and the one element in the transition metal element group is W, Ta, Mo, Ti, Zr, or Hf.

According to an eleventh aspect of the present invention, in the method of producing the electrostatic drive MEMS element in the seventh and tenth aspects, in the step of forming the insulation film, the insulation film is formed with a sputtering method.

According to a twelfth aspect of the present invention, the method of producing the electrostatic drive MEMS element in the seventh and eleventh aspects further includes the step of patterning the insulation film so that the insulation film has an undulation surface at least on a side of the movable electrode.

In the present invention, it is possible to provide the electrostatic drive MEMS element and the method of producing the electrostatic drive MEMS element capable of preventing the stiction phenomenon without an additional circuit at a low cost.

### BRIEF DESCRIPTION OF THE DRAWINGS

FIGS. 1(A) and 1(B) are schematic views showing an electrostatic drive MEMS (Micro Electro Mechanical Systems) element according to a first embodiment of the present invention, wherein FIG. 1(A) is a schematic plan view of the electrostatic drive MEMS element, and FIG. 1(B) is a schematic sectional view thereof taken along a line 1(B)-1(B) in FIG. 1(A);

FIGS. 2(A) to 2(F) are schematic sectional views showing the electrostatic drive MEMS element in a manufacturing process thereof according to the first embodiment of the present invention, wherein FIG. 2(A) is a schematic sectional view of the electrostatic drive MEMS element in a step of forming a fixed portion and a fixed electrode, FIG. 2(B) is a schematic sectional view thereof in a step of forming a sacrifice film and a second insulation film, FIG. 2(C) is a schematic sectional view thereof in a step of patterning the second insulation film and the sacrifice film, FIG. 2(D) is a schematic sectional view thereof in a step of forming a movable electrode, FIG. 2(E) is a schematic sectional view thereof in a step of patterning the movable electrode, and FIG. 2(F) is a schematic sectional view thereof in a step of removing the sacrifice film;

FIGS. 3(A) and 3(B) are schematic views showing an electrostatic drive MEMS element according to a second embodiment of the present invention, wherein FIG. 1(A) is a schematic plan view of the electrostatic drive MEMS element, and FIG. 3(B) is a schematic sectional view thereof taken along a line 3(B)-3(B) in FIG. 3(A);

FIGS. 4(A) to 4(F) are schematic sectional views showing the electrostatic drive MEMS element in a manufacturing process thereof according to the second embodiment of the present invention, wherein FIG. 4(A) is a schematic sectional view of the electrostatic drive MEMS element in a step of forming an insulation film, FIG. 4(B) is a schematic sectional view thereof in a step of patterning the insulation film, FIG. 4(C) is a schematic sectional view thereof in a step of forming and patterning a sacrifice film, FIG. 4(D) is a schematic sectional view thereof in a step of forming a movable electrode, FIG. 4(E) is a schematic sectional view thereof in a step of patterning the movable electrode, and FIG. 4(F) is a schematic sectional view thereof in a step of removing the sacrifice film;

FIGS. 5(A) and 5(B) are schematic views showing an electrostatic drive MEMS element according to a third embodiment of the present invention, wherein FIG. 1(A) is a schematic plan view of the electrostatic drive MEMS element, and FIG. 5(B) is a schematic sectional view thereof taken along a line 5(B)-5(B) in FIG. 5(A);

FIGS. 6(A) to 6(F) are schematic sectional views showing the electrostatic drive MEMS element in a manufacturing process thereof according to the second embodiment of the present invention, wherein FIG. 6(A) is a schematic sectional view of the electrostatic drive MEMS element in a step of forming an insulation film, FIG. 6(B) is a schematic sectional view thereof in a step of patterning the insulation film, FIG. 6(C) is a schematic sectional view thereof in a step of forming and patterning a sacrifice film, FIG. 6(D) is a schematic sectional view thereof in a step of forming a movable electrode, FIG. 6(E) is a schematic sectional view thereof in a step of patterning the movable electrode, and FIG. 6(F) is a schematic sectional view thereof in a step of removing the sacrifice film;

FIG. 7 is graphs showing results of compositional analysis of film samples according to the first to third embodiments of the present invention;

FIG. 8 is a graph showing a relationship between a nitrogen gas flow ratio and an electrical resistivity of the electrostatic drive MEMS element according to the first to third embodiments of the present invention;

FIG. 9 is a graph showing results of an electrical resistivity of a conventional insulation film and an electrical resistivity of the insulation film of the electrostatic drive MEMS element according to the first to third embodiments of the present invention;

FIG. 10 is a graph showing a CV property of the insulation film of the electrostatic drive MEMS element according to the first to third embodiments of the present invention;

FIG. 11 is a graph showing a CV property of a conventional insulation film.

### DETAILED DESCRIPTION OF PREFERRED EMBODIMENTS

Hereunder, preferred embodiments of the present invention will be explained with reference to the accompanying drawings. In the following description, components having similar functions are designated with the same reference numerals, and explanations thereof may be omitted if possible.

In the embodiments, an electrostatic drive MEMS (Micro Electro Mechanical Systems) element includes a substrate; a fixed electrode disposed on the substrate; a movable electrode arranged to face the fixed electrode in a vertical direction and be movable toward the fixed electrode through an electrostatic force generated between the fixed electrode and the movable electrode; and an insulation film disposed on one of an upper surface of the fixed electrode and a lower surface of the movable electrode and formed of an insulation member containing a conductive fine particle.

In the embodiments, it is suffice that the insulation film is formed of the insulation member containing the conductive fine particle, and the insulation film may contain other impurity. Further, it is suffice that the electrostatic drive MEMS element includes the insulation film. The electrostatic drive MEMS element may have a cantilever structure, a double end structure, and the like. In the embodiments described below, the electrostatic drive MEMS element has the cantilever structure.

### First Embodiment

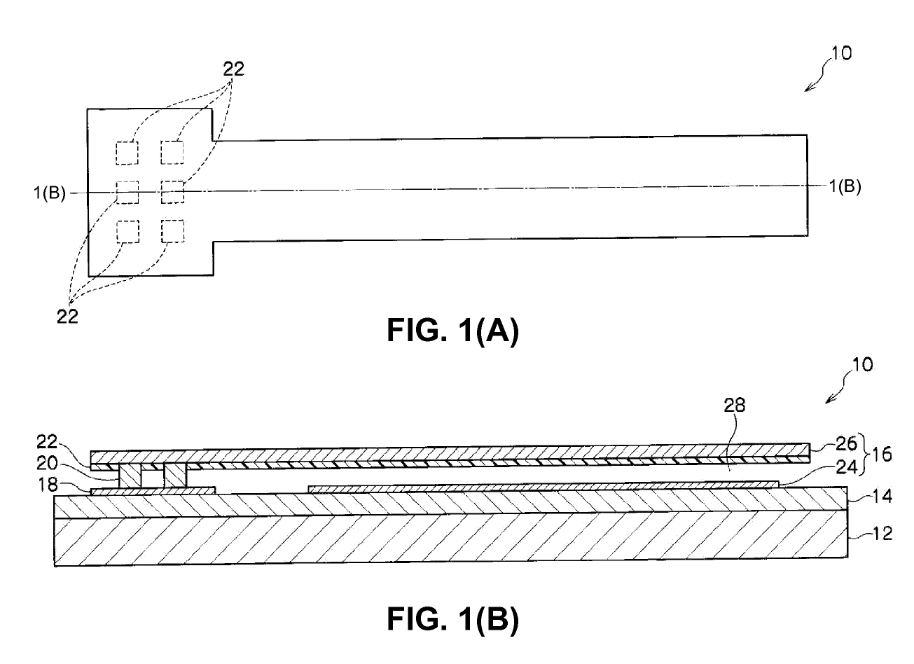

A first embodiment of the present invention will be explained. FIGS. 1(A) and 1(B) are schematic views showing an electrostatic drive MEMS element 10 according to the first embodiment of the present invention. More specifically, FIG. 1(A) is a schematic plan view of the electrostatic drive MEMS element 10, and FIG. 1(B) is a schematic sectional view thereof taken along a line 1(B)-1(B) in FIG. 1(A).

As shown in FIGS. 1(A) and 1(B), the electrostatic drive MEMS element 10 includes a first insulation film 14 formed on an upper surface of a semiconductor substrate 12. Further, the electrostatic drive MEMS element 10 includes a drive electrode 16, a fixed portion 18, supporting portions 20, and a second insulation film 22. When the semiconductor substrate 12 is formed of an insulation material, it is possible to omit the first insulation film 14.

In the embodiment, except the second insulation film 22, the semiconductor substrate 12, the first insulation film 14, the drive electrode 16, the fixed portion 18, and the supporting portions 20 may be formed of well-known materials, respectively. For example, the semiconductor substrate 12 may be formed of silicon, and the first insulation film 14 may be formed of SiN. Further, the drive electrode 16, the fixed portion 18, and the supporting portions 20 may be formed of TiN, p-Si (poly-silicon), and the like with conductivity.

In the embodiment, the drive electrode 16 is formed of a fixed electrode 24 disposed on a side of the semiconductor substrate 12 and a movable electrode 26 arranged to face the fixed electrode 24 in the vertical direction. The fixed portion 18 and the fixed electrode 24 are formed of, for example, TiN, and are formed on the first insulation film 14. The fixed portion 18, the supporting portions 20 and the movable electrode 26 have conductivity. Accordingly, the fixed portion 18 is electrically connected to the movable electrode 26, and the fixed portion 18 is further electrically connected to other elements through a wiring portion (not shown).

In the embodiment, the movable electrode 26 is formed of, for example, poly-silicon, and is formed in an elongated plate shape. The movable electrode 26 has an enlarged base portion supported on the supporting portions 20 fixed to the fixed portion 18. Accordingly, the movable electrode 26 and the supporting portions 20 constitute the cantilever structure, and a space 28 is formed between the fixed electrode 24 and the movable electrode 26.

When a voltage is applied between the movable electrode 26 and the fixed electrode 24, the movable electrode 26 deforms toward the fixed electrode 24 through an electrostatic force attracting with each other. To this end, in the embodiment, the second insulation film 22 is disposed on a lower surface of the movable electrode 26, thereby preventing short circuit between the fixed electrode 24 and the movable electrode 26. Accordingly, when a voltage is applied between the movable electrode 26 and the fixed electrode 24, the movable electrode 26 (or a MEMS beam) is capable of moving toward the space 28 between the second insulation film 22 and the fixed electrode 24.

The second insulation film 22 will be explained in more detail next. In the embodiment, the second insulation film 22 is disposed between the movable electrode 26 and the fixed electrode 24 (the drive electrode 16), and an upper surface of the second insulation film 22 contacts with the lower surface of the movable electrode 26. The second insulation film 22 has a high electrical resistivity, and is formed of an insulation member in which conductive fine particles are uniformly distributed. Further, the second insulation film 22 may be formed of an amorphous material, or an amorphous material and a fine crystalline material.

In the embodiment, when the insulation member has an electrical resistivity greater than 1×10⁵ Ωcm, it is preferred that the second insulation film 22 has an electrical resistivity greater than 1×10⁵ Ωcm, more preferably, an electrical resistivity greater than 1×10⁸ Ωcm. Although the electrical resistivity is still lower than that of TEOS-SiO₂ or SiN, i.e., a well-known high insulation material, when the second insulation film 22 has the electrical resistivity greater than 1×10⁵ Ωcm, the second insulation film 22 has a sufficient insulation property. When the second insulation film 22 has a high electrical resistivity, it is possible to sufficiently insulate between the movable electrode 26 and the fixed electrode 24.

In the embodiment, it is preferred that the conductive fine particles are uniformly distributed in the insulation member of the second insulation film 22. When the second insulation film 22 is formed with a sputtering method and the like, it is possible to uniformly distribute the conductive fine particles in the insulation member. When the conductive fine particles are uniformly distributed in the insulation member of the second insulation film 22, electric charges are leaked through the conductive fine particles and are not accumulated in the second insulation film 22, thereby preventing the stiction phenomenon.

In the embodiment, it is preferred that the second insulation film 22 is formed of an amorphous material, and the second insulation film 22 may be formed of an amorphous material containing a fine crystalline material. A metal alloy or a compound with a multi-crystalline structure tends to have a low resistivity layer in an interface between crystalline particles. When the second insulation film 22 is formed of an amorphous material, or an amorphous material and a fine crystalline material, it is possible to prevent a low resistivity layer, thereby securing insulation property.

In the embodiment, a preferred material of the second insulation film 22 includes one or more than two of WSiN, TsSiN, MoSiN, TiAlN, ZrAlN, HfAlN. In this case, the insulation member is formed of a nitride material such as SiN and AlN, and the conductive fine particles are formed of a nitride material such as WN, TaN, MoN, TiN, ZrN, and HfN.

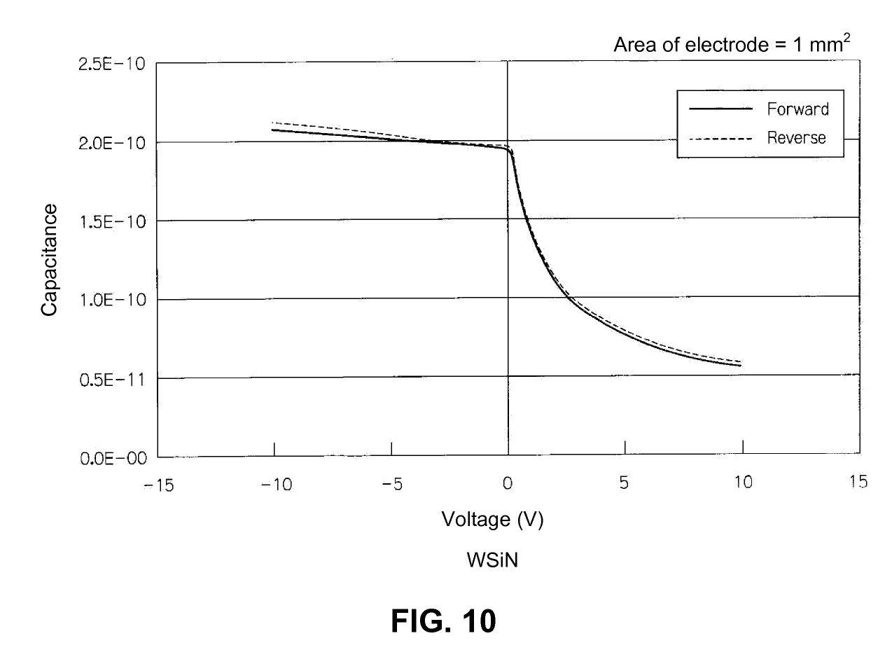

According to Reference (Chemical Bulletin No. 5, Basic Version II, published by Maruzen Co.), TiN has an electrical resistivity of about 21.7×10⁻⁶ Ωcm, and ZrN has an electrical resistivity of about 13.6×10⁻⁶ Ωcm. Accordingly, when a conductive material is defined as a low resistivity material with an electrical resistivity less than 1×10⁵ Ωcm, and an insulation material is defined as a high resistivity material with an electrical resistivity greater than 1×10⁵ Ωcm, TiN and ZrN are categorized as the conductive material. Further, SiN has an electrical resistivity of about 1×10¹⁴ Ωcm (refer to FIG. 10), and is categorized as the insulation material.

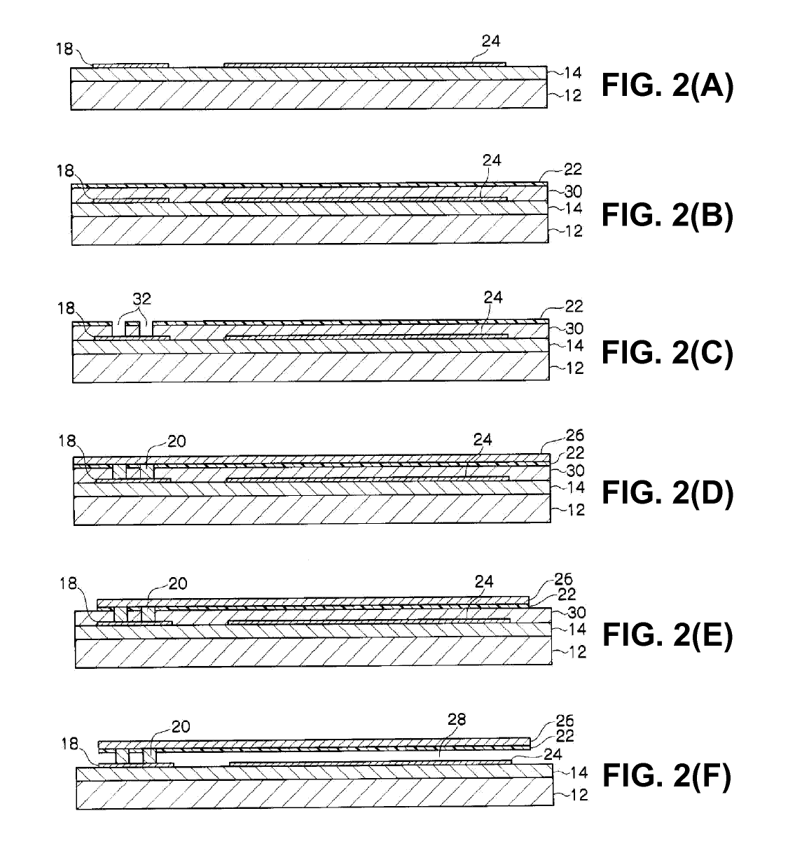

A method of producing the electrostatic drive MEMS element 10 shown in FIGS. 1(A) and 1(B) will be explained next. FIGS. 2(A) to 2(F) are schematic sectional views showing the electrostatic drive MEMS element 10 in a manufacturing process thereof according to the first embodiment of the present invention.

More specifically, FIG. 2(A) is a schematic sectional view of the electrostatic drive MEMS element 10 in a step of forming the fixed portion 18 and the fixed electrode 24, FIG. 2(B) is a schematic sectional view thereof in a step of forming a sacrifice film 30 and the second insulation film 22, FIG. 2(C) is a schematic sectional view thereof in a step of patterning the second insulation film 22 and the sacrifice film 30, FIG. 2(D) is a schematic sectional view thereof in a step of forming the movable electrode 26, FIG. 2(E) is a schematic sectional view thereof in a step of patterning the movable electrode 26, and FIG. 2(F) is a schematic sectional view thereof in a step of removing the sacrifice film 30.

In the following description, a film to be the fixed electrode 24 during manufacturing process is referred to as the fixed electrode 24. Similarly, a film to be the movable electrode 26, a film to be the fixed portion 18, a film to be the supporting portions 20, and a film to be the second insulation film 22 are referred to as the movable electrode 26, the fixed portion 18, the supporting portions 20, and the second insulation film 22, respectively.

As shown in FIG. 2(A), in the step of forming the fixed portion 18 and the fixed electrode 24, the fixed portion 18 and the fixed electrode 24 (the films to be the fixed portion 18 and the fixed electrode 24) are formed on the semiconductor substrate 12 with the first insulation film 14 formed thereon with a method appropriately selected according to a material to be used. The method includes a printing method, a wet method such as a coating method, and a chemical method such as CVD (Chemical Vapor Deposition), plasma CVD, an atomic layer deposition (ALD) method, and the like. As described above, the material to be used includes a well-known material such as TiN and the like. Thicknesses of the fixed portion 18 and the fixed electrode 24 are not limited, and may be about 100 to 300 nm. In the next step, the fixed portion 18 and the fixed electrode 24 are patterned using a combination of a photolithography method and an etching method.

As shown in FIG. 2(B), in the step of forming the sacrifice film 30 and the second insulation film 22, first, the sacrifice film 30 is formed on the first insulation film 14, the fixed portion 18, and the fixed electrode 24. The sacrifice layer 30 may be formed with a method such as plasma CVD similar to that in the step of forming the fixed portion 18 and the fixed electrode 24. A thickness of the sacrifice film 30 is not limited, and may be about 400 to 600 nm.

In the next step, the second insulation film 22 is formed on the sacrifice film 30. The second insulation film 22 may be formed with a method similar to that in the step of forming the fixed portion 18 and the fixed electrode 24. A thickness of the second insulation film 22 is not limited, and may be about 50 to 100 nm.

In the embodiment, the second insulation film 22 is formed of a combination of at least one element in a transition metal element group and one element in a semiconductor element group or a metal element group except the transition metal element group. The material includes, for example, WₓSi_{y}, TaₓSi_{y}, MoₓSi_{y}, TiₓAl_{y}, ZrₓAl_{y}, HfₓAl_{y}, and the like. A compositional ratio (y/x) is preferably less than two. When the compositional ratio (y/x) is less than two, an amount of the insulation material such as SiN and AlN becomes larger than an amount of the conductive material such as WN, TaN, MoN, TiN, ZrN, and HfN using a gas mixture containing N₂ (described later). Accordingly, the second insulation film 22 becomes the insulation member as a whole.

In the embodiment, when the second insulation film 22 is formed, the gas mixture containing nitrogen gas is introduced. More specifically, when the second insulation film 22 is formed, a flow ratio of nitrogen gas with respect to a whole portion of the gas mixture is controlled. With this procedure, it is possible to adjust the electrical resistivity of the second insulation film 22. More specifically, through controlling the flow ratio, it is possible to adjust the electrical resistivity of the second insulation film 22 from 1×10⁻⁴ Ωcm to a level greater than 1×10⁸ Ωcm (for example, up to 1×10¹² Ωcm).

In the embodiment, in addition to nitrogen gas, the gas mixture contains an inert gas such as argon and helium. The flow ratio of nitrogen gas with respect to the whole portion of the gas mixture is controlled to be greater than 80%, so that the electrical resistivity of the second insulation film 22 becomes greater than 1×10⁵ Ωcm, i.e., the level of the insulation material. More preferably, the flow ratio of nitrogen gas with respect to the whole portion of the gas mixture is controlled to be greater than 90%, so that the electrical resistivity of the second insulation film 22 becomes greater than 1×10⁸ Ωcm, i.e., the sufficient level of the insulation material.

In the embodiment, the gas mixture has a gas pressure of, for example, 0.1 Pa to 3.0 Pa (0.75 mTorr to 22.50 mTorr). More preferably, the gas mixture has a gas pressure of 0.1 Pa to 2.0 Pa (0.75 mTorr to 15.00 mTorr), thereby making it possible to obtain a film with a high density.

As shown in FIG. 2(C), in the step of patterning the second insulation film 22 and the sacrifice film 30, a part of the second insulation film 22 and the sacrifice film 30 is removed through patterning to expose the fixed portion 18, so that spaces 32 are formed for providing the supporting portions 20 of the movable electrode 26 (the MEMS beam). The patterning is not limited to a specific method, and may be a combination of, for example, the photolithography method and the etching method.

As shown in FIG. 2(D), in the step of forming the movable electrode 26, the movable electrode 26 (the film to be the movable electrode 26) is formed on the second insulation film 22 using a conductive material such as poly-silicon. The movable electrode 26 may be formed with a method similar to that in the step of forming the fixed portion 18 and the fixed electrode 24. For example, the movable electrode 26 is formed with thermal CVD using poly-silicon containing phosphorous at a concentration of 10²⁰ cm⁻³. In this step, the supporting portions 20 are formed in the spaces 32. A thickness of the movable electrode 26 is not limited, and may be about 0.5 to 10 μm.

As shown in FIG. 2(E), in the step of patterning the movable electrode 26, the movable electrode 26 and the second insulation film 22 are patterned, thereby forming the MEMS beam. The patterning is not limited to a specific method, and may be a combination of, for example, the photolithography method and the etching method.

As shown in FIG. 2(F), in the step of removing the sacrifice film 30, an entire portion of the sacrifice film 30 is removed with hydrofluoric acid and the like. When the sacrifice film 30 is removed, the space 28 is formed between the fixed electrode 24 and the movable electrode 26, thereby making the movable electrode 26 (the MEMS beam) movable. Note that the second insulation film 22 is situated on the lower surface of the movable electrode 26. Accordingly, when the movable electrode 26 moves, the movable electrode 26 does not contact with the fixed electrode 24. Through the steps described above, it is possible to produce the electrostatic drive MEMS element 10 shown in FIGS. 1(A) and 1(B).

In the electrostatic drive MEMS element 10 shown in FIGS. 1(A) and 1(B), when a voltage is applied to the drive electrode 16, the second insulation film 22 contacts with the fixed electrode 24 through an electrostatic force as an attraction force. If the second insulation film 22 is formed of an SiO₂ film or an SiN film, electric charges may be accumulated in the second insulation film 22 through frequent contacts or a prolonged contact time. When electric charges are accumulated in the second insulation film 22, the second insulation film 22 may stick to the fixed electrode 24 due to electric charges, thereby causing a phenomenon called a stiction phenomenon.

In the embodiment, in the electrostatic drive MEMS element 10 produced with the method described above, the second insulation film 22 is formed of the insulation member containing the conductive fine particles. Accordingly, electric charges are leaked through the conductive fine particles as a leak path, and are not accumulated in the second insulation film 22. As a result, it is possible to provide the electrostatic drive MEMS element 10 and the method of producing the electrostatic drive MEMS element 10 capable of preventing the stiction phenomenon without an additional circuit.

Further, in the embodiment, when the second insulation film 22 is formed, the flow ratio of nitrogen gas with respect to the whole portion of the gas mixture is controlled to be greater than 80%, so that the electrical resistivity of the second insulation film 22 becomes greater than 1×10⁵ Ωcm, i.e., the level of the insulation material. Accordingly, it is possible to adjust the electrical resistivity of the second insulation film 22 at the level of the insulation material. As a result, it is possible to provide the electrostatic drive MEMS element 10 and the method of producing the electrostatic drive MEMS element 10 capable of preventing the stiction phenomenon without an additional circuit. When the flow ratio of nitrogen gas with respect to the whole portion of the gas mixture is controlled to be greater than 90%, it is possible to adjust the electrical resistivity of the second insulation film 22 greater than 1×10⁸ Ωcm, i.e., the sufficient level of the insulation material.

Further, in the embodiment, it is possible to provide the electrostatic drive MEMS element 10 formed at the flow ratio of nitrogen capable of preventing the stiction phenomenon through the simple step such as the selection of the material and the compositional ratio of the second insulation film 22 and the control of the flow ratio of nitrogen gas in the film forming process.

Further, in the embodiment, the second insulation film 22 is formed using the conductive material as a target material. Accordingly, when the second insulation film 22 is formed, electric charges are not accumulated in the target material, thereby preventing electric charges from becoming an obstacle in the film forming process. As a result, it is possible to adopt a normal sputtering method using a conventional sputtering device in a short period of time, thereby reducing a cost as opposed to an ALD device which is limited to a specific type of film.

### Second Embodiment

A second embodiment of the present invention will be explained. In the second embodiment, an electrostatic drive MEMS element 50 has the cantilever structure and is capable of driving through an electrostatic force. Further, the electrostatic drive MEMS element 50 includes an insulation film 58 formed on an upper surface of a fixed electrode 62.

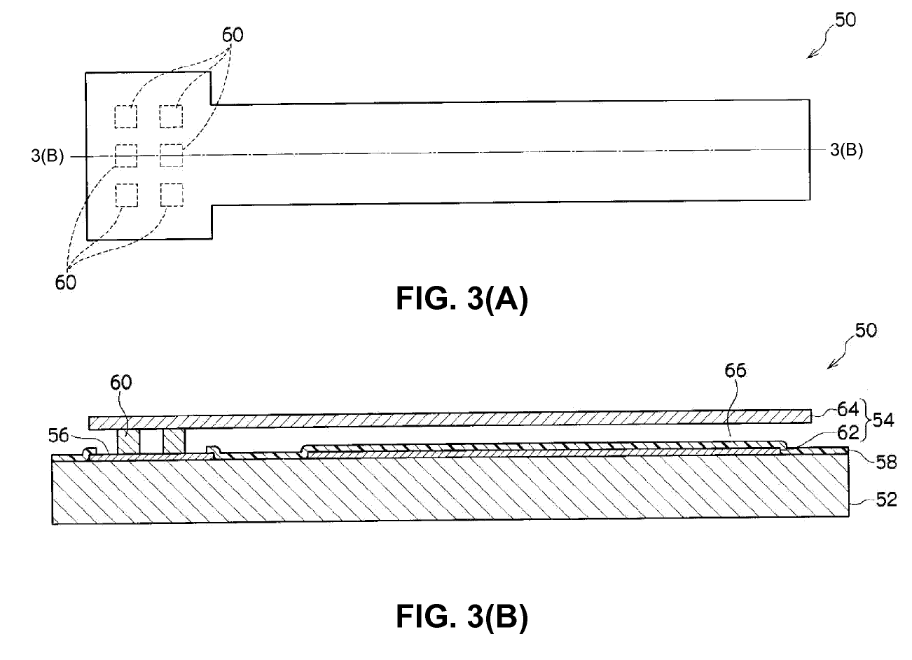

FIGS. 3(A) and 3(B) are schematic views showing the electrostatic drive MEMS element 50 according to the second embodiment of the present invention. More specifically, FIG. 3(A) is a schematic plan view of the electrostatic drive MEMS element 50, and FIG. 3(B) is a schematic sectional view thereof taken along a line 3(B)-3(B) in FIG. 3(A).

As shown in FIGS. 3(A) and 3(B), the electrostatic drive MEMS element 50 is formed on an upper surface of an insulation substrate 52. Further, the electrostatic drive MEMS element 50 includes a drive electrode 54, a fixed portion 56, the insulation film 58, and supporting portions 60.

In the embodiment, the drive electrode 54 is formed of the fixed electrode 62 disposed on a side of the insulation substrate 52 and a movable electrode 64 arranged to face the fixed electrode 62 in a vertical direction. The movable electrode 64 is formed in an elongated plate shape. Further, the movable electrode 64 is fixed to the fixed portion 56 and supported on the portions 60, thereby constituting the cantilever structure. Accordingly, a space 66 is formed between the fixed electrode 62 and the movable electrode 64.

When a voltage is applied between the fixed electrode 62 and the movable electrode 64, the movable electrode 64 deforms toward the fixed electrode 62 through an electrostatic force attracting with each other. To this end, in the embodiment, the insulation film 58 is disposed on the upper surface of the fixed electrode 62, thereby preventing short circuit between the fixed electrode 62 and the movable electrode 64. Accordingly, when a voltage is applied between the fixed electrode 62 and the movable electrode 64, the movable electrode 64 (or the MEMS beam) is capable of moving toward the space 66 between the fixed electrode 62 and the insulation film 58.

Other components in the second embodiment are similar to those in the first embodiment, and explanations thereof are omitted.

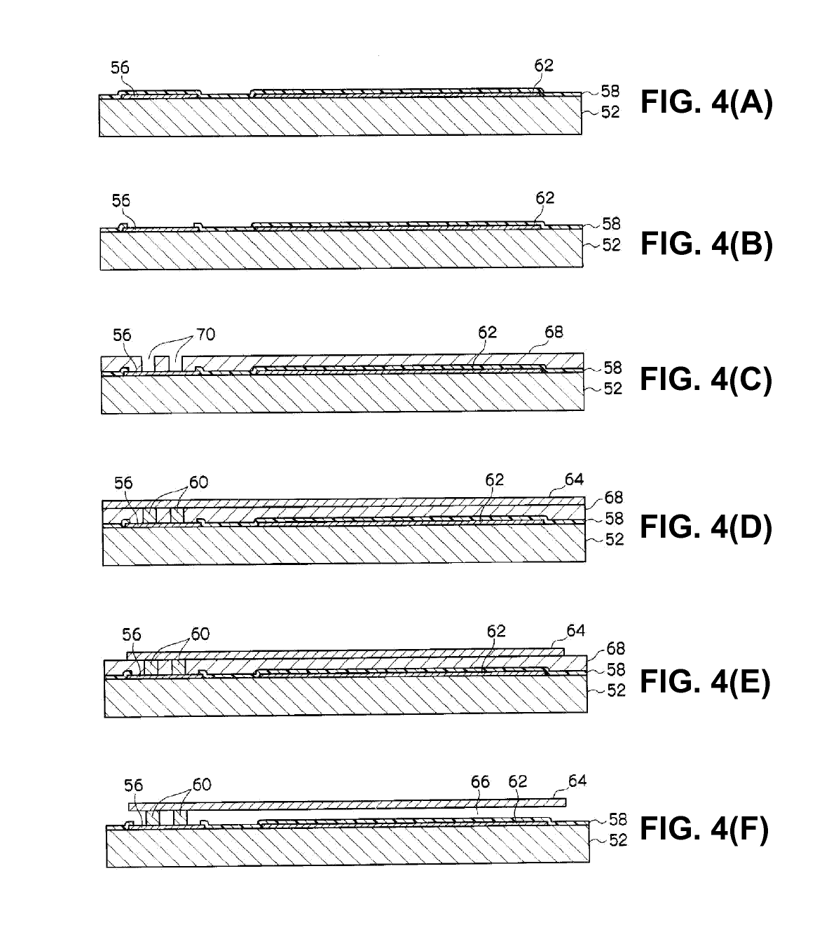

A method of producing the electrostatic drive MEMS element 50 shown in FIGS. 3(A) and 3(B) will be explained next. FIGS. 4(A) to 4(F) are schematic sectional views showing the electrostatic drive MEMS element 50 in a manufacturing process thereof according to the second embodiment of the present invention.

More specifically, FIG. 4(A) is a schematic sectional view of the electrostatic drive MEMS element 50 in a step of forming the insulation film 58, FIG. 4(B) is a schematic sectional view thereof in a step of patterning the insulation film 58, FIG. 4(C) is a schematic sectional view thereof in a step of forming and patterning a sacrifice film 68, FIG. 4(D) is a schematic sectional view thereof in a step of forming the movable electrode 64, FIG. 4(E) is a schematic sectional view thereof in a step of patterning the movable electrode 64, and FIG. 4(F) is a schematic sectional view thereof in a step of removing the sacrifice film 68.

In the following description, a film to be the fixed electrode 62 during manufacturing process is referred to as the fixed electrode 62. Similarly, a film to be the movable electrode 64, a film to be the fixed portion 56, a film to be the supporting portions 60, and a film to be the insulation film 58 are referred to as the movable electrode 64, the fixed portion 56, the supporting portions 60, and the insulation film 58, respectively.

As shown in FIG. 4(A), in the step of forming the insulation film 58, first, the fixed portion 56 and the fixed electrode 62 are formed on the insulation substrate 52 with a method similar to that shown in FIG. 2(A). Then, the insulation film 58 is formed on the fixed electrode 62 with a method similar to that shown in FIG. 2(B).

As shown in FIG. 4(B), in the step of patterning the insulation film 58, a part of the insulation film 58 is removed, so that the fixed portion 56 is exposed. The patterning is not limited to a specific method, and may be a combination of, for example, the photolithography method and the etching method.

As shown in FIG. 4(C), in the step of forming and patterning the sacrifice film 68, first, the sacrifice film 68 is formed with a method similar to that shown in FIG. 2(B). Then, a part of the sacrifice film 68 is removed through patterning to expose the fixed portion 56, so that spaces 70 are formed for providing the supporting portions 60 of the movable electrode 64 (the MEMS beam). The patterning is not limited to a specific method, and may be a combination of, for example, the photolithography method and the etching method.

As shown in FIG. 4(D), in the step of forming the movable electrode 64, the movable electrode 64 (the film to be the movable electrode 64) is formed on the sacrifice film 68 using a conductive material such as poly-silicon. The movable electrode 64 may be formed with a method similar to that shown in FIG. 2(D). In this step, the supporting portions 60 are formed in the spaces 70.

As shown in FIG. 4(E), in the step of patterning the movable electrode 64, the movable electrode 64 is patterned, thereby forming the MEMS beam. The patterning is not limited to a specific method, and may be a combination of, for example, the photolithography method and the etching method.

As shown in FIG. 4(F), in the step of removing the sacrifice film 68, an entire portion of the sacrifice film 68 is removed with hydrofluoric acid and the like. When the sacrifice film 68 is removed, the movable electrode 64 (the MEMS beam) becomes movable. Note that the insulation film 58 is situated on the upper surface of the fixed electrode 62. Accordingly, when the movable electrode 64 moves, the movable electrode 64 does not contact with the fixed electrode 62. Through the steps described above, it is possible to produce the electrostatic drive MEMS element 50 shown in FIGS. 3(A) and 3(B).

In the electrostatic drive MEMS element 50 shown in FIGS. 3(A) and 3(B), when a voltage is applied to the drive electrode 54, the movable electrode 64 contacts with the insulation film 58 through an electrostatic force as an attraction force. If the insulation film 58 is formed of an SiO₂ film or an SiN film, electric charges may be accumulated in the insulation film 58 through frequent contacts or a prolonged contact time. When electric charges are accumulated in the insulation film 58, even if the voltage applied to the drive electrode 54 is turned off, the movable electrode 64 may keep sticking to the insulation film 58 on the side of the fixed electrode 62, thereby causing the stiction phenomenon.

In the embodiment, in the electrostatic drive MEMS element 50 produced with the method described above, the insulation film 58 is formed of the insulation member containing the conductive fine particles. Accordingly, electric charges are leaked through the conductive fine particles as a leak path, and are not accumulated in the insulation film 58. As a result, it is possible to provide the electrostatic drive MEMS element 50 and the method of producing the electrostatic drive MEMS element 50 capable of preventing the stiction phenomenon without an additional circuit.

Further, in the embodiment, when the insulation film 58 is formed, the flow ratio of nitrogen gas with respect to the whole portion of the gas mixture is controlled to be greater than 80%, so that the electrical resistivity of the insulation film 58 becomes greater than 1×10⁵ Ωcm, i.e., the level of the insulation material. Accordingly, it is possible to adjust the electrical resistivity of the insulation film 58 at the level of the insulation material. As a result, it is possible to provide the electrostatic drive MEMS element 50 and the method of producing the electrostatic drive MEMS element 50 capable of preventing the stiction phenomenon without an additional circuit. When the flow ratio of nitrogen gas with respect to the whole portion of the gas mixture is controlled to be greater than 90%, it is possible to adjust the electrical resistivity of the insulation film 58 greater than 1×10⁸ Ωcm, i.e., the sufficient level of the insulation material.

Further, in the embodiment, the insulation film 58 is formed using the conductive material as a target material. Accordingly, when the insulation film 58 is formed, electric charges are not accumulated in the target material, thereby preventing electric charges from becoming an obstacle in the film forming process. As a result, it is possible to adopt a normal sputtering method using a conventional sputtering device in a short period of time, thereby reducing a cost as opposed to an ALD device which is limited to a specific type of film.

Further, as compared with the first embodiment, in the second embodiment, the insulation film 58 is formed on the side of the fixed electrode 62. Accordingly, it is possible to prevent a stress in the insulation film 58 from affecting the movable electrode 64 provided as the MEMS beam.

### Third Embodiment

A third embodiment of the present invention will be explained. In the third embodiment, an electrostatic drive MEMS element 80 has the cantilever structure and is capable of driving through an electrostatic force. Further, the electrostatic drive MEMS element 80 includes a plurality of insulation films formed on the upper surface of the fixed electrode 62.

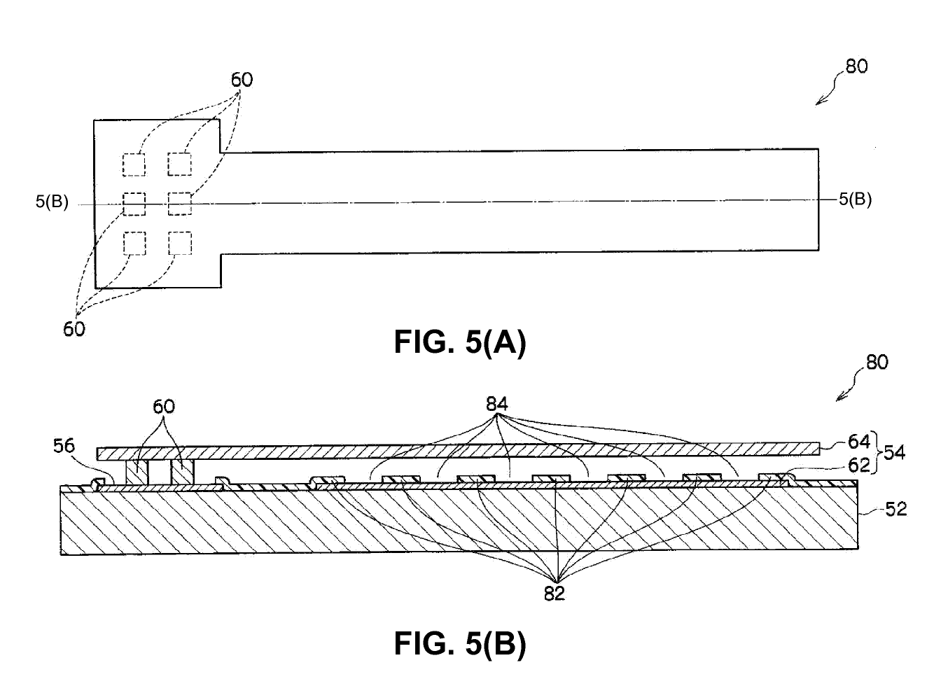

FIGS. 5(A) and 5(B) are schematic views showing the electrostatic drive MEMS element 50 according to the third embodiment of the present invention. More specifically, FIG. 5(A) is a schematic plan view of the electrostatic drive MEMS element 80, and FIG. 5(B) is a schematic sectional view thereof taken along a line 5(B)-5(B) in FIG. 5(A).

In the embodiment, the electrostatic drive MEMS element 80 includes a plurality of insulation films 82 having a configuration different from that of the insulation film 58. Other than the insulation films 82, the electrostatic drive MEMS element 80 has a configuration similar to that of the electrostatic drive MEMS element 50. Accordingly, in the following description, only the insulation films 82 will be explained.

In the embodiment, the insulation films 82 are formed at a plurality of locations on the surface of the fixed electrode 62 with an interval 84 in between, so that the insulation films 82 have an undulation structure.

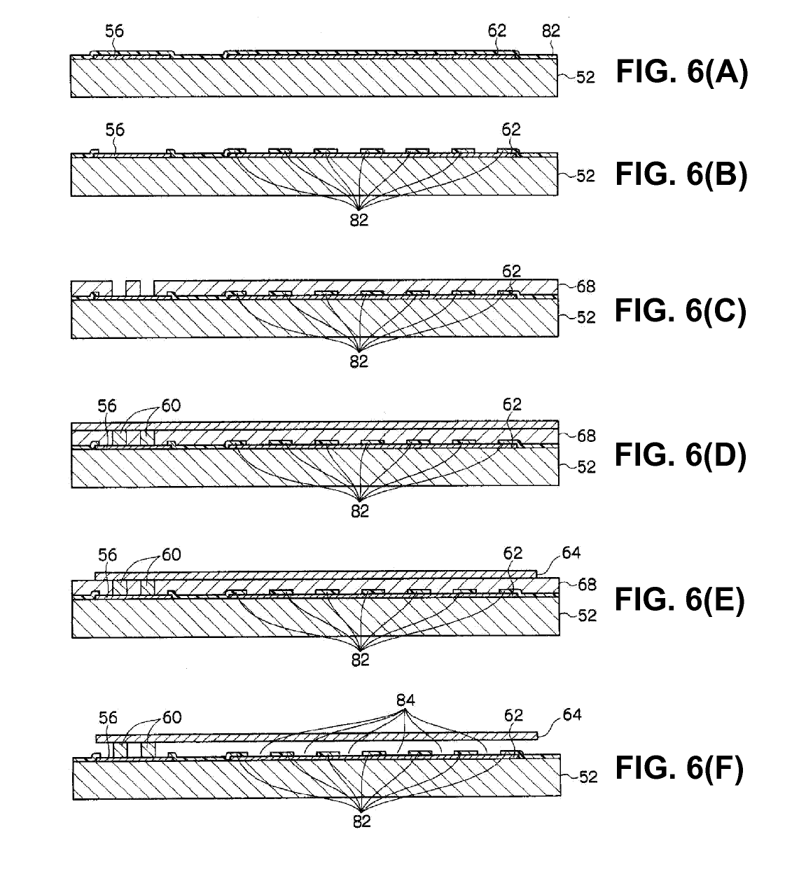

A method of producing the electrostatic drive MEMS element 80 shown in FIGS. 5(A) and 5(B) will be explained next. FIGS. 6(A) to 6(F) are schematic sectional views showing the electrostatic drive MEMS element 80 in a manufacturing process thereof according to the third embodiment of the present invention.

More specifically, FIG. 6(A) is a schematic sectional view of the electrostatic drive MEMS element 50 in a step of forming the insulation films 82, FIG. 6(B) is a schematic sectional view thereof in a step of patterning the insulation films 82, FIG. 6(C) is a schematic sectional view thereof in a step of forming and patterning the sacrifice film 68, FIG. 6(D) is a schematic sectional view thereof in a step of forming the movable electrode 64, FIG. 6(E) is a schematic sectional view thereof in a step of patterning the movable electrode 64, and FIG. 6(F) is a schematic sectional view thereof in a step of removing the sacrifice film 68.

As shown in FIG. 6(A), in the step of forming the insulation films 82, the insulation films 82 (a film to be the insulation films 82) are formed on the fixed electrode 62 with a method similar to that shown in FIG. 2(B).

As shown in FIG. 6(B), in the step of patterning the insulation films 82, portions of the insulation films 82 on the fixed portion 56 and the fixed electrode 62 are removed, so that the fixed portion 56 and a part of the fixed electrode 62 are exposed. Accordingly, the insulation films 82 are formed at a plurality of locations on the fixed electrode 62 with the interval 84 in between, so that the insulation films 82 have an undulation structure.

In the third embodiment, as described above, the insulation films 82 are formed at a plurality of locations on the fixed electrode 62 with the interval 84 in between. Accordingly, as compared with the first embodiment and the second embodiment, the insulation films 82 cover in a smaller area.

In the configuration described above, the insulation between the fixed electrode 62 and the movable electrode 64 depends on an environment at the intervals 84. More specifically, the insulation between the fixed electrode 62 and the movable electrode 64 depends on whether the environment at the intervals 84 is air, an arbitrary gas such as nitrogen gas, argon gas, and the like, or vacuum. Accordingly, when the environment at the intervals 84 becomes an insulation member, it is possible to suppress a leak current even when the insulation films 82 have an electrical resistivity lower than that of a film formed of SiO₂ or SiN, i.e., a well-known insulation member with high electrical resistivity.

The present invention is not limited to the configurations of the electrostatic drive MEMS element 10, the electrostatic drive MEMS element 50, and the electrostatic drive MEMS element 80 in the first to third embodiments described above. As far as the MEMS element is the electrostatic dive type, the second insulation film 22, the insulation film 58, or the insulation films 82 may be provided all of the MEMS elements. The present invention is applicable to an MEMS switch, an MEMS transducer, an MEMS acceleration sensor, and the like.

Further, the first embodiment may be combined with the second embodiment. More specifically, the second insulation film 22 may be formed on the lower surface of the movable electrode 26, so that the second insulation film 22 is disposed on the two surfaces between the drive electrode 16.

Further, in the third embodiment described above, the insulation films 82 are formed at a plurality of locations on the fixed electrode 62 with the interval 84 in between, so that the insulation films 82 have an undulation structure. Alternatively, the third embodiment may be combined with the first embodiment. More specifically, the insulation films 82 may be formed at a plurality of locations on the lower surface of the movable electrode 64 with an interval in between. With this configuration, the insulation films 82 have a smaller area, thereby reducing a stress of the insulation films 82 applied to the movable electrode 64 to be the MEMS beam.

Further, the insulation films 82 do not necessarily have the undulation structure in the third embodiment. It is suffice that the insulation films 82 have the undulation structure on the side of the movable electrode 64. In this case, when the insulation films 82 are patterned, a portion of the insulation films 82 on the side of the fixed electrode 62 may remain through adjusting an etching time.

Further, in the embodiments described above, when the second insulation film 22, the insulation film 58, and the insulation films 82 are formed, the gas mixture containing the inert gas such as argon, helium, and the like in addition to nitrogen gas. Alternatively, when the second insulation film 22, the insulation film 58, and the insulation films 82 are formed, only nitrogen gas or a gas mixture of nitrogen gas and oxygen gas may be used.

Further, in the embodiments described above, when the second insulation film 22, the insulation film 58, and the insulation films 82 are formed, the sputtering method is used. Alternatively, there may be adopted other deposition methods such as an electron beam deposition method, a physical vapor deposition (PVD) method such as an ion plating method, various chemical vapor deposition (CVD) methods, a liquid deposition such as a plating method and a sol-gel method. When the second insulation film 22, the insulation film 58, and the insulation films 82 are formed with the sputtering method, it is possible to form the film at a low temperature.

An experiment for evaluating the electrostatic drive MEMS element 10, the electrostatic drive MEMS element 50, and the electrostatic drive MEMS element 80 was conducted. In the experiment, six film samples, i.e., the film sample No. 1 to the film sample No. 6, were prepared and evaluated as follows.

First, a WSiN film to be used as the second insulation film 22, the insulation film 58, or the insulation films 82 was formed on a p-type Si substrate. More specifically, the WSiN film was formed using a sputtering device Endura 5500 (a product of Applied Materials, Inc.) with a WSiₓ (x=2.0 to 2.8) film forming target as a target at a gas pressure of 5 to 9 mTorr and an RF power of 2 kW. Among the six film samples, i.e., the film sample No. 1 to the film sample No. 6, when the WSiN film was formed, a flow ratio of nitrogen gas with respect to a whole portion of the gas mixture (N₂/(Ar+N₂)) was adjusted between 0% and 100%.

More specifically, in the film sample No. 1, the flow ratio of nitrogen gas with respect to the whole portion of the gas mixture was adjusted at 0%. In the film sample No. 2, the flow ratio of nitrogen gas with respect to the whole portion of the gas mixture was adjusted at 40%. In the film sample No. 3, the flow ratio of nitrogen gas with respect to the whole portion of the gas mixture was adjusted at 60%. In the film sample No. 4, the flow ratio of nitrogen gas with respect to the whole portion of the gas mixture was adjusted at 80%. In the film sample No. 5, the flow ratio of nitrogen gas with respect to the whole portion of the gas mixture was adjusted at 90%. In the film sample No. 6, the flow ratio of nitrogen gas with respect to the whole portion of the gas mixture was adjusted at 100%.

An X-ray diffraction measurement was conducted on the film samples No. 1 to No. 6 using an X-ray diffractometer JDX-8030 (a product of KOEL Ltd.) under conditions such as an X-ray: Cu—Kα, 30 KV, 20 mA; a measurement range: 20 degree to 50 degree; a step width: 0.05 degree; and a scanning speed 3 deg/min.

According to the X-ray diffraction measurement, it was found that none of the film samples No. 1 to No. 6 exhibited a diffraction peak. Accordingly, it was confirmed that the film samples No. 1 to No. 6 were formed of an amorphous material.

Further, the film samples No. 1 to No. 6 were annealed (850° C., 60 min, under a nitrogen environment) after the formation thereof. After the annealing, the film sample No. 1 exhibited a diffraction peak of WSi₂. From the film sample No. 2 to the film sample No. 5, as the flow ratio of nitrogen gas increased, the film sample exhibited a weaker diffraction peak of WSi₂. The film sample No. 6, whose the flow ratio of nitrogen gas was 100%, exhibited no diffraction peak of WSi₂. Accordingly, it was confirmed that the film sample has the amorphous structure sufficiently stable relative to the thermal process when the flow ratio of nitrogen gas was sufficiently high.

A compositional analysis was conducted on the film samples No. 1 to No. 6 using an X-ray Photoelectron Spectroscopy M-PROBE (a product of Surface Science Co.) under conditions such as an X-ray: Al—Kα; a detection angle: 35 degree (θ=55°); and analyzed elements W4f, O1s, Si2p, and N1s.

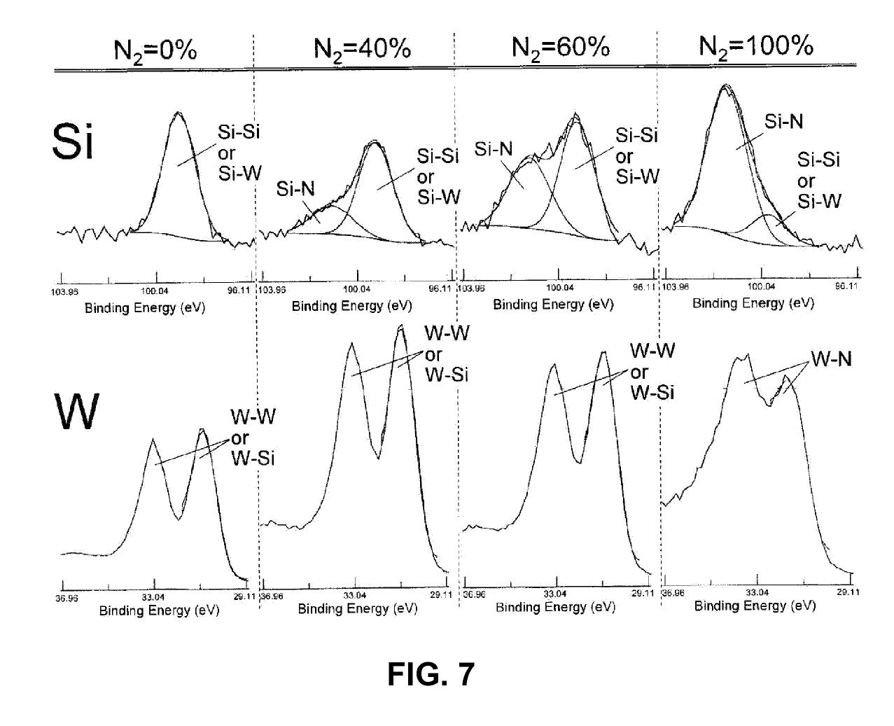

FIG. 7 is graphs showing results of the compositional analysis of the film samples No. 1 to No. 3 and No. 6 according to the first to third embodiments of the present invention.

As shown in FIG. 7, according to the results of the compositional analysis of the film samples, there were confirmed the W—Si bonding or the Si—Si bonding, the W—W bonding or the W—Si bonding, the Si—N bonding, and the W—N bonding.

As described above, the films samples No. 1 to No. 3, the flow ratio of nitrogen gas with respect to the whole portion of the gas mixture was adjusted from 0% to 60%. Further, the WSiₓ (x=2.0 to 2.8) film forming target was used as the target. Accordingly, it was considered that the films samples No. 1 to No. 3 exhibited a diffraction peak attributed to the W—Si bonding and contained WSiₓ as a main component. As the flow ratio of nitrogen gas with respect to the whole portion of the gas mixture increased, the diffraction peak attributed to the W—Si bonding became stronger, indicating that the compositional ratio of SiN in the film samples increased.

Further, when the flow ratio of nitrogen gas was 100% in the film sample No. 6, it was confirmed that Si existed as SiN and X existed as WN. When the film sample No. 6 was formed, an amount of W was smaller than that of Si. Accordingly, it was confirmed that the film sample No. 6 contained SiN, i.e., an insulation material, as a main component.

From the results of the compositional analysis and the X-ray diffraction measurement, the film sample formed of WSiN had a structure, in which Si existed as SiN, i.e., an insulation material, and the conductive fine particles formed of WN are distributed therein.

An electrical resistivity measurement was conducted on the film samples No. 1 to No. 6. In the electrical resistivity measurement, an Al electrode was formed on each of the film samples No. 1 to No. 6 formed on the p-type Si substrate. The Al electrode had an area of 1 mm². Then, a negative electrode was connected to the Al electrode, and a positive electrode was connected to the p-type Si substrate.

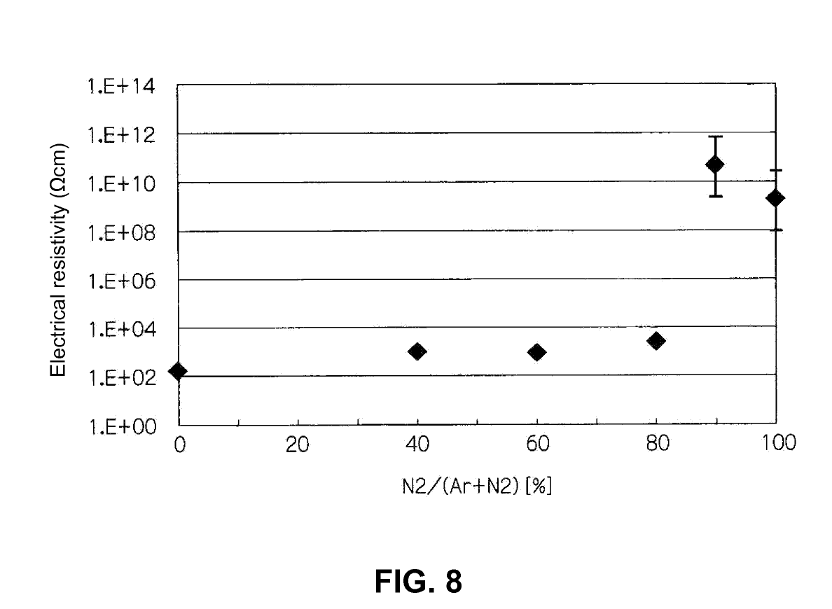

According to results of the electrical resistivity measurement, a relationship between the flow ratio of nitrogen gas and the electrical resistivity was established. FIG. 8 is a graph showing the relationship between the nitrogen gas flow ratio and the electrical resistivity.

As shown in FIG. 8, in the film samples No. 1 to No. 4 formed at the nitrogen gas flow ratio between 0% and 80%, the electrical resistivity slightly increased within a range of 1×10² Ωcm to 1×10⁴ Ωcm as the nitrogen gas flow ratio increased. When the nitrogen gas flow ratio exceeded 80% to 90%, the electrical resistivity significantly increased. More specifically, the film samples No. 5 and No. 6 formed at the nitrogen gas flow ratio between 90% and 100% exhibited the electrical resistivity of 1×10⁸ Ωcm to 1×10¹¹ Ωcm. This phenomenon has not disclosed in Patent Reference.

When a conductive material is defined as a low resistivity material with an electrical resistivity less than 1×10⁵ Ωcm, and an insulation material is defined as a high resistivity material with an electrical resistivity greater than 1×10⁵ Ωcm, the film samples No. 1 to No. 4 were categorized as the conductive material and the film samples No. 5 and No. 6 were categorized as the insulation material. In other word, when the film sample formed of WSiN was formed at the flow ratio of nitrogen gas with respect to the whole portion of the gas mixture greater than 80%, it was possible to form the film sample formed of the insulation material.

From the results of the compositional analysis and the X-ray diffraction measurement, in addition to the results shown in FIG. 8, the film samples No. 1 to No. 4 formed at the nitrogen gas flow ratio between 0% and 80% were formed of WSiN as the main component, so that the entire portion of the film samples No. 1 to No. 4 was formed of the conductive material with the low electrical resistivity. On the other hand, the film samples No. 5 and No. 6 formed at the nitrogen gas flow ratio between 90% and 100% were formed of SiN as the main component, so that the entire portion of the film samples No. 5 and No. 6 was formed of the insulation material with the high electrical resistivity.

Through the experiment described above, it was confirmed that it is possible to adjust the electrical resistivity of the film samples formed of WSiN from 1×10² Ωcm to 1×10¹¹ Ωcm through controlling the flow ratio of nitrogen gas. Note that the adjustable range of the electrical resistivity depends on the compositional ratio of the film samples formed of WSiN. More specifically, through adjusting the compositional ratio, it is possible to the electrical resistivity from 1×10⁻⁴ Ωcm to 1×10¹⁴ Ωcm, corresponding to the electrical resistivity of the SiN film.

As a comparison, an electrical resistivity of a conventional insulation member such as a TEOS-SiO₂ film and an SiN film was measured with a method similar to that in the experiment of measuring the electrical resistivity of the film samples No. 1 to No. 6. More specifically, after the TEOS-SiO₂ film and the SiN film were formed on the p-type Si substrate, the Al electrode was formed on the TEOS-SiO₂ film and the SiN film. The Al electrode had an area of 1 mm². Then, the negative electrode was connected to the Al electrode, and the positive electrode was connected to the p-type Si substrate.

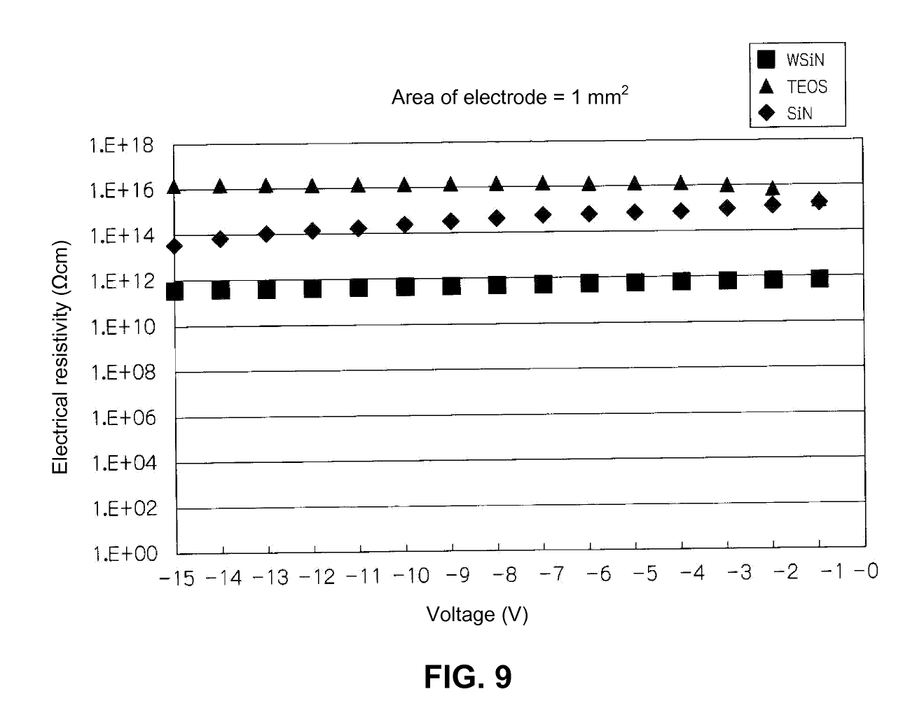

FIG. 9 is a graph showing results of the electrical resistivity of the conventional insulation films, i.e., the TEOS-SiO₂ film and the SiN film, and the electrical resistivity of the film sample No. 5 formed of WSiN at the nitrogen gas flow ratio of 90%. As shown in FIG. 9, while the film sample No. 5 formed of WSiN exhibited the electrical resistivity lower than those of the TEOS-SiO₂ film and the SiN film, the electrical resistivity of the film sample No. 5 was about 1×10¹⁰ Ωcm, thereby maintaining the sufficient insulation.

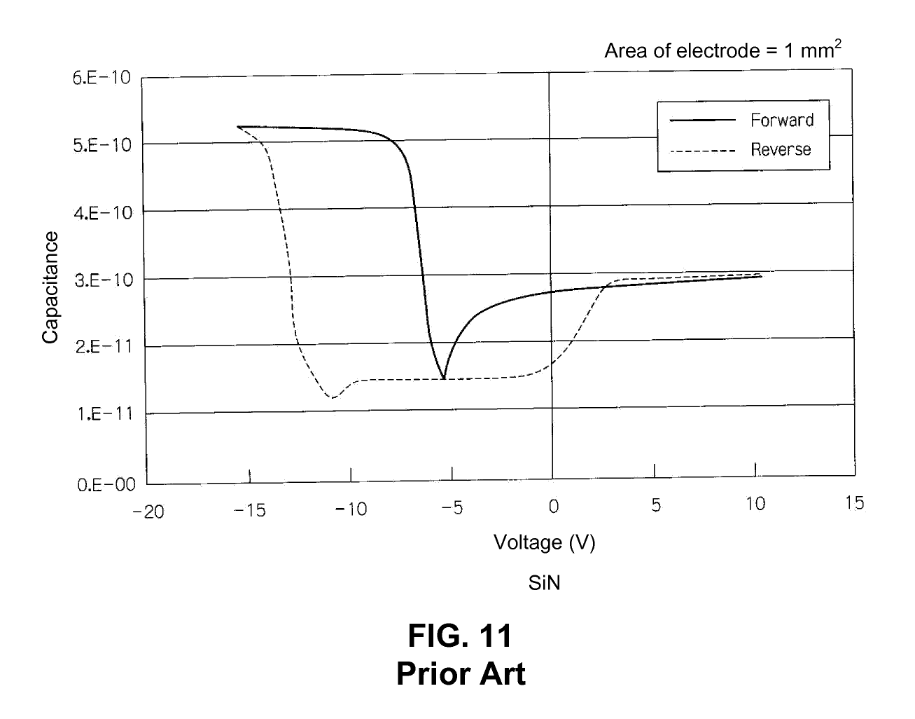

A capacitance voltage (CV) property of the film sample No. 5 and the SiN film as a comparative sample was measured. FIG. 10 is a graph showing the CV property of the film sample No. 5. FIG. 11 is a graph showing a CV property of the SiN film.

As shown in FIGS. 10 and 11, the CV property was measured in a forward direction, in which a voltage was changed from negative to positive, and in a reverse direction, in which a voltage was changed from positive to negative.

As shown in FIGS. 10 and 11, the SiN film exhibited the CV property in the forward direction different from that in the reverse direction, thereby indicating that electrical charges were trapped in the SiN film. On the other hand, the film sample No. 5 exhibited the CV property in the forward direction similar to that in the reverse direction, thereby indicating that electrical charges were not trapped in the SiN film.

As described above, in the film sample No. 5 formed of WSiN, the conductive fine particles formed of WN were dispersed in the insulation member formed of SiN. Accordingly, the conductive fine particles formed of WN electrically shielded the insulation member formed of SiN, so that the insulation member formed of SiN did not function as an electric charge trapping film. Accordingly, when the second insulation film 22, the insulation film 58, and the insulation films 82 of the electrostatic drive MEMS element 10, the electrostatic drive MEMS element 50, and the electrostatic drive MEMS element 80 have the configuration formed of WSiN similar to that of the film sample No. 5, it is possible to prevent electric charges from being accumulated in the second insulation film 22, the insulation film 58, and the insulation films 82.

As described above, in the film samples No. 5 and No. 6, the conductive fine particles formed of WN were dispersed in the insulation member formed of SiN. Accordingly, the conductive fine particles formed of WN became the leak path, thereby preventing electric charges from being accumulated therein. Accordingly, when the second insulation film 22, the insulation film 58, and the insulation films 82 of the electrostatic drive MEMS element 10, the electrostatic drive MEMS element 50, and the electrostatic drive MEMS element 80 have the configuration similar to those of the film samples No. 5 and No. 6, it is possible to prevent the stiction phenomenon without an additional circuit.

As described above, when the film samples No. 5 and No. 6 were formed, the flow ratio of nitrogen gas with respect to the whole portion of the gas mixture was controlled to be greater than 80%. Accordingly, the electrical resistivity of the film samples No. 5 and No. 6 became greater than 1×10⁵ Ωcm, i.e., the level of the insulation material. As a result, when the second insulation film 22, the insulation film 58, and the insulation films 82 of the electrostatic drive MEMS element 10, the electrostatic drive MEMS element 50, and the electrostatic drive MEMS element 80 have the configuration similar to those of the film samples No. 5 and No. 6, it is possible to adjust the electrical resistivity of the second insulation film 22, the insulation film 58, and the insulation films 82 at the level of the insulation material, thereby preventing the stiction phenomenon.

More preferably, when the film samples No. 5 and No. 6 were formed, the flow ratio of nitrogen gas with respect to the whole portion of the gas mixture is controlled to be greater than 90%. Accordingly, the electrical resistivity of the film samples No. 5 and No. 6 became greater than 1×10⁸ Ωcm, i.e., the sufficient level of the insulation material.

Further, it was possible to form the film samples No. 5 and No. 6 through the simple step such as the selection of the material and the compositional ratio thereof, and the control of the flow ratio of nitrogen gas in the film forming process.

Further, it is possible to form the film samples No. 5 and No. 6 with the normal sputtering method. As a result, it is possible to form the film samples No. 5 and No. 6 in a short period of time. A sputtering device is applicable to other steps, thereby reducing a cost as opposed to an ALD device which is limited to a specific type of film.

The disclosure of Japanese Patent Application No. 2009-044562, filed on Feb. 26, 2009, is incorporated in the application by reference.

While the invention has been explained with reference to the specific embodiments of the invention, the explanation is illustrative and the invention is limited only by the appended claims.

What is claimed is:

1. An electrostatic drive MEMS (Micro Electro Mechanical Systems) element, comprising:
a substrate;
a fixed electrode disposed on the substrate;
a movable electrode arranged to face the fixed electrode in a vertical direction and be movable toward the fixed electrode through an electrostatic force generated between the fixed electrode and the movable electrode; and
an insulation film disposed on one of an upper surface of the fixed electrode and a lower surface of the movable electrode and formed of an insulation member containing a conductive fine particle.

2. The electrostatic drive MEMS element according to claim 1, wherein said insulation member is formed of a nitride containing at least one element in a semiconductor element group or a metal element group except a transition metal element group, said conductive fine particle being formed of a nitride containing at least one element in the transition metal element group.

3. The electrostatic drive MEMS element according to claim 1, wherein said insulation member is formed of SiN or AlN, said conductive fine particle being formed of WN, TaN, MoN, TiN, ZrN or HfN.

4. The electrostatic drive MEMS element according to claim 1, wherein said insulation member is formed of an amorphous material, said conductive fine particle being formed of an amorphous material or a fine crystalline material.

5. The electrostatic drive MEMS element according to claim 1, wherein said insulation film has an undulation surface at least on a side of the movable electrode.

6. The electrostatic drive MEMS element according to claim 1, wherein said insulation film is disposed on the upper surface of the fixed electrode.

7. A method of producing an electrostatic drive MEMS (Micro Electro Mechanical Systems) element, comprising the steps of:
forming a fixed electrode on a substrate using a conductive material;
forming an insulation film on an upper surface of the fixed electrode using a gas mixture having a flow ratio of nitrogen gas greater than 80% so that at least one element in a transition metal element group and one element in a semiconductor element group or a metal element group except the transition metal element group are used as raw materials;
forming a sacrifice film on the insulation film;
forming a movable electrode on the sacrifice film using a conductive material; and
removing the sacrifice film.

8. A method of producing an electrostatic drive MEMS (Micro Electro Mechanical Systems) element, comprising the steps of:
forming a fixed electrode on a substrate using a conductive material;
forming a sacrifice film on the fixed electrode;
forming an insulation film on an upper surface of the sacrifice film using a gas mixture having a flow ratio of nitrogen gas greater than 80% so that at least one element in a transition metal element group and one element in a semiconductor element group or a metal element group except the transition metal element group are used as raw materials;
forming a movable electrode on the insulation film using a conductive material; and
removing the sacrifice film.

9. The method of producing the electrostatic drive MEMS element according to claim 7, wherein, in the step of forming the insulation film, said insulation film is formed so that the one element in the semiconductor element group or the metal element group has a compositional ratio greater than two relative to the one element in the transition metal element group.

10. The method of producing the electrostatic drive MEMS element according to claim 8, wherein, in the step of forming the insulation film, said insulation film is formed so that the one element in the semiconductor element group or the metal element group has a compositional ratio greater than two relative to the one element in the transition metal element group.

11. The method of producing the electrostatic drive MEMS element according to claim 7, wherein, in the step of forming the insulation film, said insulation film is formed so that the one element in the semiconductor element group or the metal element group is Si or Al, and the one element in the transition metal element group is W, Ta, Mo, Ti, Zr, or Hf.

12. The method of producing the electrostatic drive MEMS element according to claim 8, wherein, in the step of forming the insulation film, said insulation film is formed so that the one element in the semiconductor element group or the metal element group is Si or Al, and the one element in the transition metal element group is W, Ta, Mo, Ti, Zr, or Hf.

13. The method of producing the electrostatic drive MEMS element according to claim 7, wherein, in the step of forming the insulation film, said insulation film is formed with a sputtering method.

14. The method of producing the electrostatic drive MEMS element according to claim 8, wherein, in the step of forming the insulation film, said insulation film is formed with a sputtering method.

15. The method of producing the electrostatic drive MEMS element according to claim 7, further comprising the step of patterning the insulation film so that the insulation film has an undulation surface at least on a side of the movable electrode.

16. The method of producing the electrostatic drive MEMS element according to claim 8, further comprising the step of patterning the insulation film so that the insulation film has an undulation surface at least on a side of the movable electrode.
